(19) United States
(12) Patent Application Publication
(10) Pub. No.: US 2014/0068316 A1
(43) Pub. Date: Mar. 6, 2014

(54) DETERMINATION SUPPORT APPARATUS, DETERMINING APPARATUS, MEMORY CONTROLLER, SYSTEM, AND DETERMINATION METHOD

(71) Applicant: FUJITSU LIMITED, Kawasaki-shi (JP)

(72) Inventors: Michitaka Hashimoto, Kawasaki (JP); Noriyuki Tokuhiro, Kawasaki (JP)

(21) Appl. No.: 13/909,105

(22) Filed: Jun. 4, 2013

(30) Foreign Application Priority Data
Aug. 29, 2012 (JP) 2012-189310

(51) Int. Cl. G06F 1/08; H03L 7/085

(52) U.S. Cl. CPC G06F 1/08; H03L 7/085
USPC 713/601; 327/156

(57) ABSTRACT

A determination support apparatus includes a detecting unit that detects a phase difference between a first clock signal and a second clock signal that is identical in frequency to the first clock signal; a control unit that controls delay of at least one among the first clock signal and the second clock signal such that the detected phase difference becomes less than a given amount; and an acquiring unit that acquires values of a given clock signal among the first clock signal and the second clock signal, among which at least one has been subject to delay control by the control unit, wherein the acquiring unit acquires the values of the given clock signal at a timing that is based on a clock signal that is other than the given clock signal and among the first clock signal and the second clock signal.

### CROSS REFERENCE TO RELATED APPLICATIONS

This application is based upon and claims the benefit of priority of the prior Japanese Patent Application No. 2012-189310, filed on Aug. 29, 2012, the entire contents of which are incorporated herein by reference.

### FIELD

The embodiments discussed herein are related to a determination support apparatus, a determining apparatus, a memory controller, a system, and a determination method.

### BACKGROUND

A known technology detects a phase difference by encoding the phase difference of multiple signals (see, for example, International Publication No. 2010/32830 and Japanese Laid-Open Patent Publication No. 2010-273118).

Another technology determines whether failure has occurred at an apparatus that adjusts phases (see, for example, Japanese Laid-Open Patent Publication No. H8-221149). Technology is further known that re-executes an instruction if an error occurs at an apparatus (see, for example, Japanese Patent No. S61-30298). Yet another technology is known that does not output a parity alarm when with respect memory, the timing of the writing and of the reading of data abnormally converge (see, for example, Japanese Laid-Open Patent Publication No. 2003-143118).

In another known technology, a memory controller detects the phase difference between an internal clock signal and a data strobe signal received from the memory, adjusts the phase of the received data strobe signal, and resets the timing of the received data (hereinafter, referred to as “conventional art example”) (see, for example, International Publication No. 2011/077574).

For example, the memory synchronizes with the data strobe signal and transmits data. Since the data strobe signal is generated by the memory based on an internal clock signal, there is no frequency difference. However, the timing at which the data strobe signal and the data signal reach the memory controller varies for each of the signals depending on changes in the delay of the signals consequent to operating environment conditions such as temperature, supplied voltage, etc. Therefore, the memory controller detects the difference in phase between the internal clock signal and the data strobe signal, and based on the detected phase difference, adjusts the delay of each signal.

If there is an abrupt clock signal change that delay adjustment cannot keep pace with, an error may occur with the data signal, which is generated based on the clock signal. However, with the conventional technologies, a problem arises in that whether the error occurred consequent to an abrupt change in the clock signal or consequent to another factor cannot be determined.

### SUMMARY

According to an aspect of an embodiment, a determination support apparatus includes a detecting unit that detects a phase difference between a first clock signal and a second clock signal that is identical in frequency to the first clock signal; a control unit that controls delay of at least any one among the first clock signal and the second clock signal such that the detected phase difference becomes less than a given amount; and an acquiring unit that acquires values of a given clock signal among the first clock signal and the second clock signal, among which at least one has been subject to delay control by the control unit, wherein the acquiring unit acquires the values of the given clock signal at a timing that is based on a clock signal that is other than the given clock signal and among the first clock signal and the second clock signal, among which at least one has been subject to delay control.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram depicting an example of a determining apparatus;

FIG. 2 is a diagram of another example of the determining apparatus;

FIG. 3 is a diagram of an example of a memory controller according to a first example;

FIG. 4 is a diagram of an example of a control unit and a phase/error detecting unit;

FIG. 5 is a table of error information;

FIG. 6 is a table of phase information;

FIGS. 7A, 7B, 7C, and 7D are timing charts of a data strobe signal and an internal clock signal;

FIG. 8 is a diagram of an example of the memory controller according to the second example;

FIG. 9 is a diagram depicting a determination support process and a determination process;

FIG. 10 is a flowchart of the determination process; and

FIG. 11 is a diagram of an example of a motherboard to which the memory controller according to the embodiment has been applied.

### DESCRIPTION OF EMBODIMENTS

Preferred embodiments of a determination support apparatus, a determining apparatus, a memory controller, system, and a determination method will be explained with reference to the accompanying drawings.

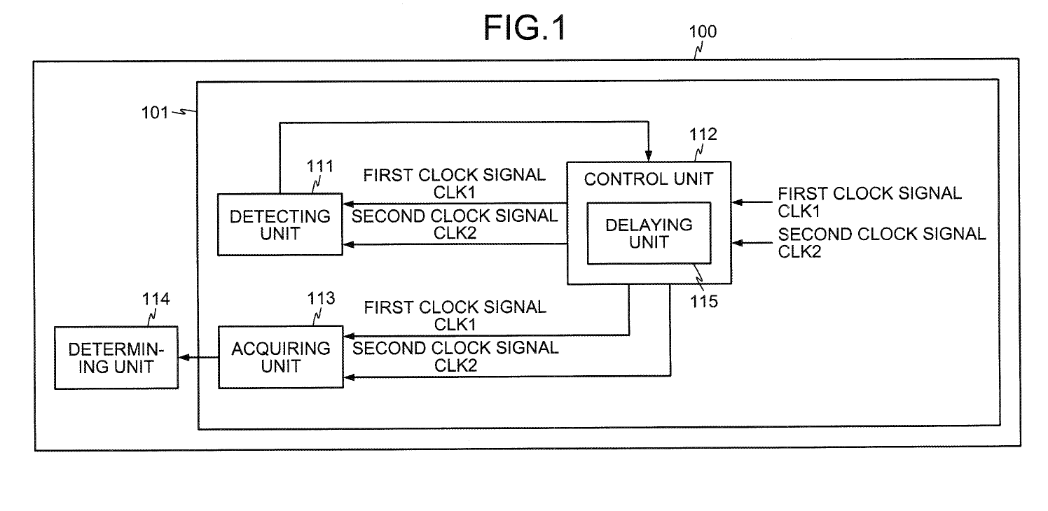

FIG. 1 is a diagram depicting an example of a determining apparatus. A determination support apparatus 101 provides data that can determine whether among 2 clock signals of the same frequency, an abrupt change has occurred in either clock signal. An abrupt change of a clock signal occurs consequent to power supply noise and jitter. Based on the data that can determine whether an abrupt change of a clock signal has occurred, a determining apparatus 100 determines whether an abrupt clock signal change has occurred.

The determining apparatus 100 includes the determination support apparatus 101 and a determining unit 114. The determination support apparatus 101 includes a detecting unit 111, a control unit 112, and an acquiring unit 113. These units, for example, are configured by elements such as inverters (which are NOT gates), AND gates, OR gates, latches, flip flops (FF), capacitors, resistors, and transistors.

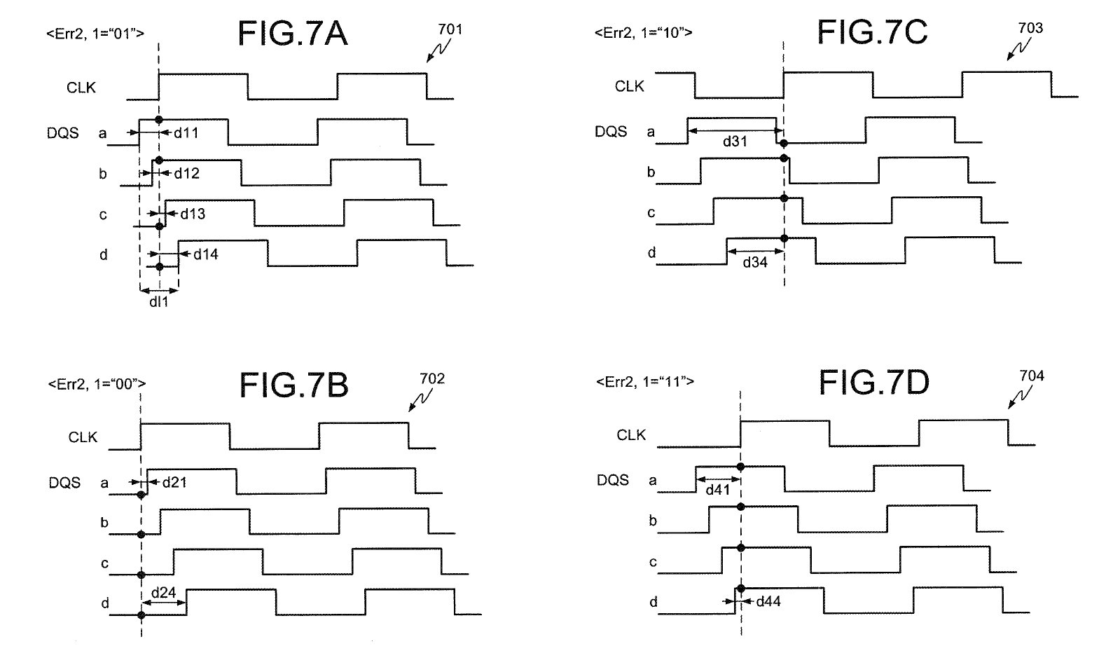

The detecting unit 111 detects a phase difference between a first clock signal CLK1 and a second clock signal CLK2, which is of the same frequency as the first clock signal CLK1. The control unit 112 controls the delay of at least one among the first clock signal CLK1 and the second clock signal CLK2 such that the phase difference detected by the detecting unit 111 becomes less than a given amount. The given amount is a value of 0 or greater and a value that does not result in phase abnormality. If the phase difference significantly exceeds the given amount, phase abnormality occurs. An example of the given amount will be described with reference to FIGS. 7A, 7B, 7C, and 7D. The phase difference detection method by the detecting unit 111, for example, may employ the conventional art example described above. For example, by feedback control and based on past phase difference detection results, the control unit 112 adjusts the current delay of the second clock signal CLK2. For example, the control unit 112 includes a delaying unit 115 and may adjust the delay that the delaying unit 115 induces on the second clock signal CLK2.

Among the first clock signal CLK1 and the second clock signal CLK2, among which at least one has been subject to delay control by the control unit 112, the acquiring unit 113 acquires values of one of the clock signals. The acquiring unit 113 acquires values of the clock signal at a timing that is based on the other clock signal among the first clock signal CLK1 and the second clock signal CLK2. For example, the acquiring unit 113 may be implemented by latches and FFs. The timing based on the other clock signal may be, for example, the timing of the rising edge of the other clock signal, or the falling edge of the other clock signal.

Taking as an example, a case in which the delay of the second clock signal CLK2 is controlled by the control unit 112, the acquiring unit 113 acquires at a timing that is based on the first clock signal CLK1, values of the second clock signal CLK2 that has been delayed under the control of the control unit 112. For example, if an abrupt change has not occurred in either the first clock signal CLK1 or the second clock signal CLK2, the phase difference can be followed by feedback control. Therefore, the phase difference between the first clock signal CLK1 and the second clock signal CLK2 is adjusted to approach 0. On the other hand, if an abrupt change has occurred in either of the clock signals, feedback control cannot keep pace with the change. Consequently, if values of the second clock signal CLK2, which has been delayed, are acquired at a timing based on the first clock signal CLK1, a value that differs from a predetermined value may be acquired. Therefore, by determining whether each acquired value is the predetermined value, whether an abrupt clock signal change has occurred can be determined. The predetermined value is a fixed value preliminarily determined at the design of the determining apparatus 100.

The determining unit 114 determines whether the values acquired by the acquiring unit 113 are the predetermined value. For example, upon determining that an acquired value is the predetermined value, the determining unit 114 determines that no abrupt clock signal change has occurred, and upon determining that an acquired value is not the predetermined value, the determining unit determines that an abrupt clock signal change has occurred.

As a result, effects consequent to an abrupt clock signal change can be observed. For example, when data processing or data reading at a timing based on the clock signals is performed and a failure in the execution of the data processing or an error in the data reading occurs, whether the failure or abnormality occurred consequent to the clock signal is determined.

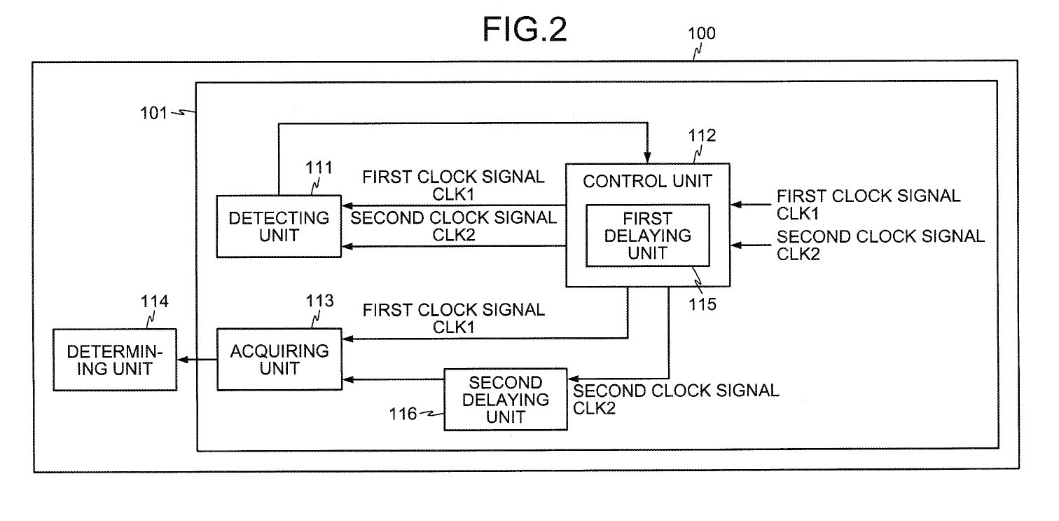

FIG. 2 is a diagram of another example of the determining apparatus. The determination support apparatus 101 depicted in FIG. 2 further includes a second delaying unit 116. Each of the units, for example, may be configured by elements such as inverters, AND gates, OR gates, latches, FFs, capacitors, resistors, and transistors.

The second delaying unit 116 delays by a second given amount, either signal among the first clock signal CLK1 and the second clock signal CLK2, among which at least one has been subject to delay control by the control unit 112. The second given amount is a delay amount of 0 or greater and causes the phase difference to be less than a phase difference judged to be a phase abnormality. A detailed example of the second given amount will be described with reference to FIGS. 7A, 7B, 7C, and 7D. In the example depicted in FIG. 2, the second delaying unit 116 delays by the second given amount, the second clock signal CLK2 among the first clock signal CLK1 and the second clock signal CLK2, among which at least one has been subject to delay by the control unit 112.

Among the first clock signal CLK1 and the second clock signal CLK2, among which at least one has been subject to delay control by the control unit 112, the acquiring unit 113 acquires values of either clock signal (e.g., CLK2) before the clock signal (CLK2) is subject to delay by the second delaying unit 116. The acquiring unit acquires the values of the clock signal (CLK2) at a timing that is based on the other clock signal (CLK1) among the first clock signal CLK1 and the second clock signal CLK2, among which at least one has been subject to delay control by the control unit 112. Subsequently, after the clock signal (CLK2) has been subject to delay by the second delaying unit 116, the acquiring unit 113 acquires values of the clock signal (CLK2), at the timing that is based on the other clock signal (CLK1).

Further, among the first clock signal CLK1 and the second clock signal CLK2, among which at least one has been subject to delay control by the control unit 112, the acquiring unit 113 may acquire values of the other clock signal (CLK1) at a timing that is based on the clock signal (CLK2) before the clock signal (CLK2) is subject to delay by the second delaying unit 116. Furthermore, the acquiring unit 113 may acquire the values of the other clock signal (CLK1) at a timing that is based on the clock signal (CLK2) after the clock signal (CLK2) has been subject to delay by the second delaying unit 116.

For example, at a timing based on the first clock signal CLK1, the acquiring unit 113 acquires the value of the second clock signal CLK2 after the second clock signal CLK2 has been subject to delay by the second delaying unit 116 and acquires the value of the second clock signal CLK2 before the second clock signal CLK2 has been subject to delay by the second delaying unit 116. The determining apparatus 100 depicted in FIG. 2 enables data to be obtained that can determine whether an abrupt clock signal change has occurred that causes the phase of the first clock signal CLK1 to lag behind the phase of the second clock signal CLK2. Further, the determining apparatus 100 depicted in FIG. 2 enables data to be obtained that can determine whether an abrupt clock signal change has occurred that causes the phase of the first clock signal CLK1 to be ahead of the phase of the second clock signal CLK2. Consequently, the determining apparatus 100 depicted in FIG. 2 can further improve determination accuracy as compared to the determining apparatus 100 depicted in FIG. 1.

The memory controller of the embodiment and that controls access to memory will be described as an example of the determination support apparatus and the determining apparatus. Here, prior to description of the memory controller according to the embodiment, a case will be described in which an abrupt clock signal change has occurred with a conventional memory controller.

As described with the background technology, conventionally, the data strobe signal output by the memory is generated based on a clock signal supplied by the memory controller and consequently, no difference in frequency arises in the communication of data between the memory controller and the memory. Further, the timing at which the data strobe signal and a data signal reached the memory controller varies depending on changes in signal delay consequent to operating environment conditions such as temperature, supplied voltage, etc. Signal delay is delay occurring consequent to the capacitance of the memory controller, the printed substrate, the wiring of memory elements as well as the capacitance between the wirings. Timing variations consequent to delay discrepancies resulting from increased data transfer speeds cannot be ignored. Therefore, according to an existing technique, a memory controller adjusts the delay of received signals, based the phase difference between the internal clock signal of the memory controller and the data strobe signal. Initial property variations of a product equipped with memory and a memory controller are substantially invariant during the operation warranty period of the product. Initial property variations include variations consequent to processing and manufacturing, and are minimally affected by temperature and temporal changes of the product.

Meanwhile, conventionally, the effect of an abrupt clock signal change consequent to power supply noise or jitter is small compared to the effect of a delay discrepancy resulting from initial property variations and changes in the operating environment. With conventional memory operation speeds in the past, an abrupt clock signal change fell within a timing margin and therefore, the frequency of data errors occurring consequent to an abrupt clock signal change was low. A timing margin is a condition such as a maximum or minimum signal delay period for a logic circuit such as an FF to operate properly, or a setup/hold period for a circuit input signal. However, with the recent operating speeds of memory having a high-speed memory interface, the frequency of data errors resulting from an abrupt clock signal change consequent to an insufficient timing margin is increasing. For example, although the data width is 1000 [ps] for transmission at 1 [Gbps], the data width is 500 [ps] for transmission at 2 [Gbps]. If the timing margin is set to be 50 [%] of the data width, although the timing margin is 500 [ps] for transmission at 1 [bps], the timing margin is 250 [ps] for transmission at 2 [Gbps]. Therefore, for the recent operating speeds of memory having a high-speed memory interface, the timing margin has become significantly smaller compared to that for past conventional speeds.

Conventionally, even if an error in the data read from the memory is detected, whether the error occurred consequent to an abrupt clock signal change or another factor cannot be determined. Consequently, when a data error occurs, the error is handled as a failure of the memory and the operation of the memory is suspended and the memory is replaced, even though an error consequent to an abrupt clock signal change may be resolved by merely re-reading the data and obtaining error-free data.

In the present embodiment, whether an error in data read from the memory is consequent to an abrupt clock signal change or another factor is determined. As a result, if the error is consequent to an abrupt clock signal change, error-free data may be obtained by merely re-reading the data, enabling suspension of the memory to be prevented and the frequency of memory replacement to be reduced.

Here, a first example and a second example will be described separately. In the first example, a determination support process is performed by a memory controller, and a determination process is performed by a processor (e.g., a central processing unit (CPU) that accesses the memory controller. In the second example, the determination support process and the determination process are both performed by the memory controller.

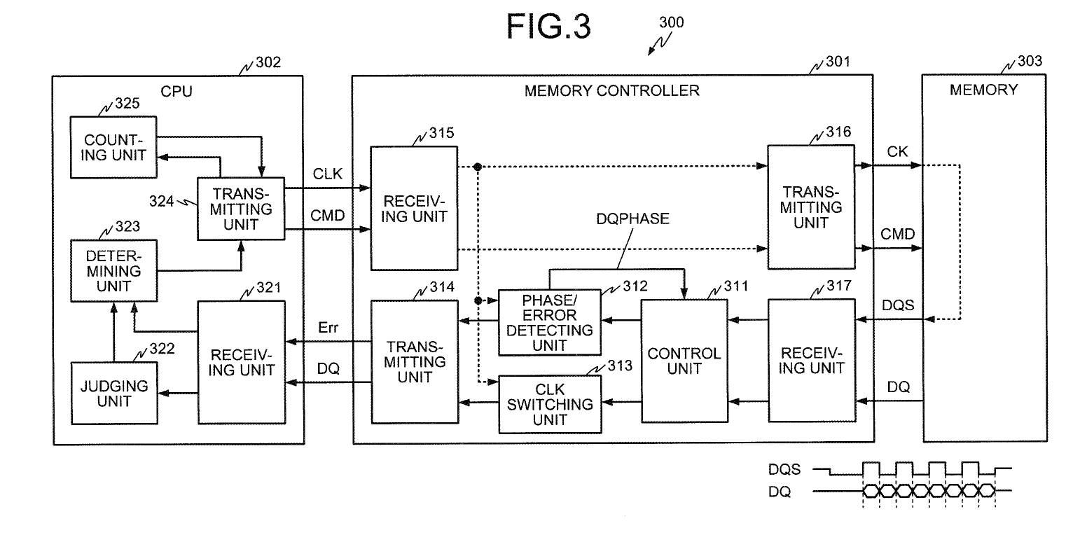

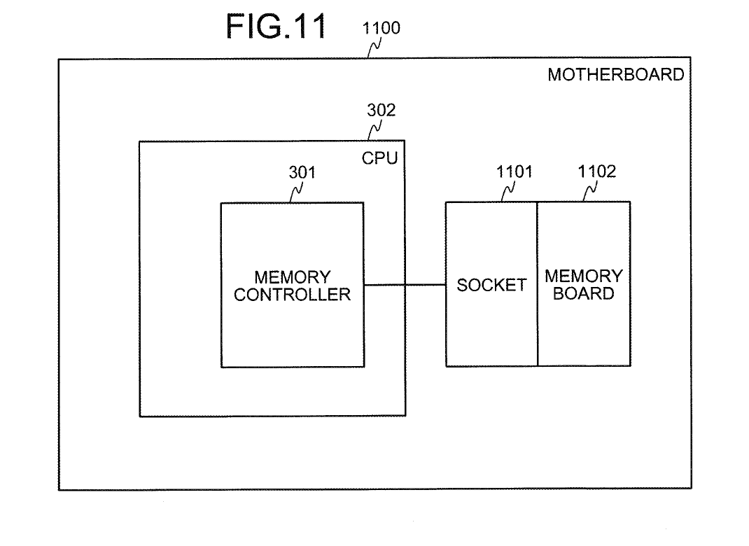

FIG. 3 is a diagram of an example of the memory controller according to the first example. FIG. 3 depicts a system 300 that includes a CPU 302, a memory controller 301, and memory 303. A motherboard depicted in FIG. 11 can be given as an example of the system 300.

The memory 303 is a device that stores data. The CPU 302 is a device that executes data processing, and when performing operations of the reading or writing of data with respect to the memory 303 while performing the data processing, the CPU 302 transmits reading and writing instructions to the memory controller 301. Based on the reading and writing instructions from the CPU 302, the memory controller 301 performs control of the reading and writing of the data with respect to the memory 303.

The memory controller 301 includes a control unit 311, a phase/error detecting unit 312, a CLK switching unit 313, a transmitting unit 314, a receiving unit 315, a transmitting unit 316, and a receiving unit 317. The CPU 302, for example, includes a receiving unit 321, a judging unit 322, a determining unit 323, a transmitting unit 324, and a counting unit 325. These units, for example, are configured by elements such as inverters (which are NOT gates), AND gates, OR gates, latches, FFs, capacitors, resistors, and transistors.

The transmitting unit 324, when a read operation is initiated, transmits a clock signal CLK and a command signal CMD that indicates a read instruction to the memory controller 301.

The receiving unit 315 receives the clock signal CLK and the command signal CMD from the CPU 302. If the command signal CMD indicates a read instruction to read data from the memory 303, the transmitting unit 316 transmits to the memory 303, an internal clock signal CK that is based on the received clock signal CLK and a command signal CMD that indicates a read instruction to read from the memory 303. In this example, the memory controller 301 is assumed to transmit the internal clock signal CK to the memory 303 since the memory controller 301 may transmit the received clock signal CLK to the memory 303, after changing the phase of the clock signal CLK or without changing the phase of the clock signal CLK.

The memory 303, upon receiving the internal clock signal CK and the command signal CMD indicating a read instruction from the memory controller 301, generates a data strobe signal DQS based on the internal clock signal CK. The memory 303 transmits to the memory controller 301, a data signal DQ that corresponds to the read instruction, at a timing based on the data strobe signal DQS. For example, as depicted in FIG. 3, the timing based on the data strobe signal DQS may be both the timing of the rising edge of the data strobe signal DQS and the timing of the falling edge of the data strobe signal DQS. Further, for example, the timing based on the data strobe signal DQS may any one among the timing of the rising edge of the data strobe signal DQS and the timing of the falling edge of the data strobe signal DQS. The memory 303 transmits the data strobe signal DQS together with the data signal DQ to the memory controller 301.

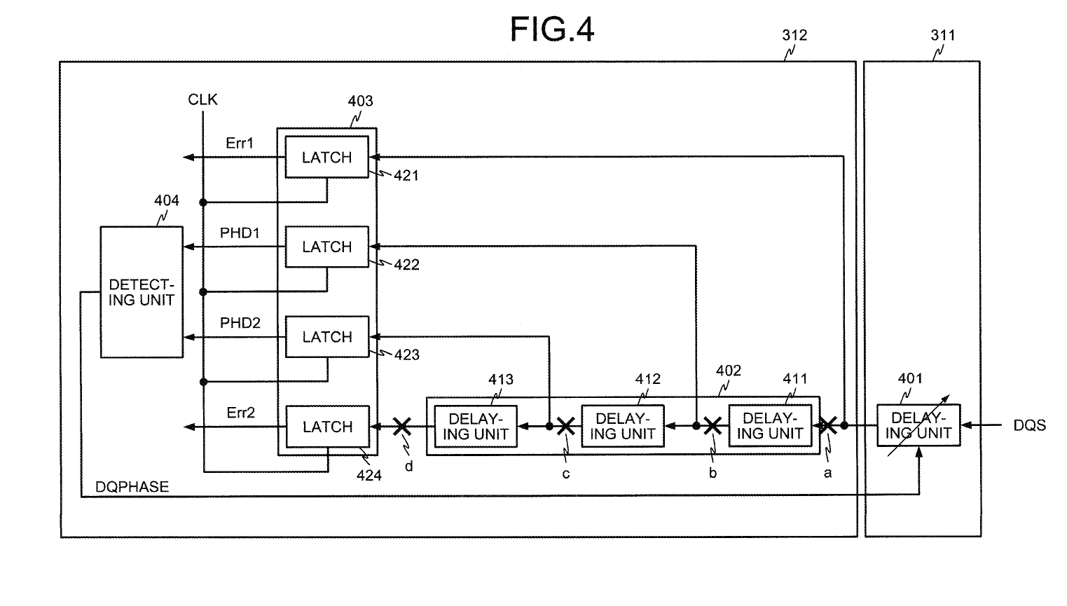

The receiving unit 317 receives the data strobe signal DQS and the data signal DQ from the memory 303. The control unit 311 controls the delay of the received data strobe signal DQS such that the phase detected by the phase/error detecting unit 312 becomes less than the given amount. The phase/error detecting unit 312 detects the phase difference between the internal clock signal CLK and the received data strobe signal DQS. The phase/error detecting unit 312 further acquires at a timing based on the internal clock signal CLK, values of the data strobe signal DQS that has been delayed under the control of the control unit 311. The control unit 311 and the phase/error detecting unit 312 will be described in detail with reference to FIGS. 4 to 7.

The CLK switching unit 313 re-times the received data signal DQ, based on the internal clock signal CLK and the data strobe signal DQS whose delay has been controlled by the control unit 311. Since re-timing may be performed by a process identical to that recited in the conventional art example above, further description is omitted. The transmitting unit 314 transmits to the CPU 302, the error information Err and the data signal DQ that has been subject to switching by CLK switching unit 313 at a timing based on the internal clock signal CLK.

The receiving unit 321 receives the data signal DQ and the error information Err from the memory controller 301. The judging unit 322 judges whether the data signal DQ has an error. For example, the judging unit 322 can judge whether the data signal DQ has an error by a cyclic redundancy check (CRC), a parity check, etc. If the judging unit 322 has judged that the data signal DQ has an error, the determining unit 323 determines whether the error information Err is predetermined value.

If the determining unit 323 determines that the error information Err is not the predetermined value, the transmitting unit 324 transmits the same read instruction and the clock signal CLK to the memory controller 301. The counting unit 325 counts the number of times that the same read instruction is transmitted to the memory controller 301 by the transmitting unit 324. The transmitting unit 324 does not transmit the same read instruction if the count obtained by the counting unit 325 is greater than or equal to the given count. The given count is, for example, determined by the designer of the system 300 and preliminarily stored to a storage device such as a register in the CPU 302.

As a result, the read operation can be prevented from being recursively performed indefinitely. Further, if the occurrence of an abrupt change has been determined, by performing the read operation again, the potential of performing error-free reading is high. Irrespective of the high potential of performing error-free reading and despite repeated execution of the read operation, if error-free reading still cannot be performed, a failure of the memory 303 and/or the memory controller 301 may have occurred. Accordingly, by using the counting unit 325 and limiting the number of executions of the read operation, the CPU 302 can determine whether a failure of the memory 303 and/or the memory controller 301 has occurred.

For example, the CPU 302 may suspend operation if the count obtained by the counting unit 325 is greater than or equal to the given count.

The CPU 302 judges that an abrupt clock change has not occurred, if the determining unit 323 determines that the error information Err is the predetermined value. For example, the CPU 302 may judge that an error consequent to a factor other than the clock has occurred and suspend the operation of the memory 303 and/or the memory controller 301.

FIG. 4 is a diagram of an example of the control unit and the phase/error detecting unit. The control unit 311, for example, includes a first delaying unit 401. The first delaying unit 401 corresponds to the delaying unit 115 depicted in FIGS. 1 and 2 (referred to as first delaying unit 115 in FIG. 2). The phase/error detecting unit 312 includes a second delaying unit 402, an acquiring unit 403, and a detecting unit 404. The second delaying unit 402 corresponds to the second delaying unit 116 depicted in FIG. 2. For the sake of convenience in description, in FIG. 4, “x” indicated by reference characters a to d represent nodes.

The control unit 311, based on the phase difference detected by the phase/error detecting unit 312, controls the delay induced on the data strobe signal DQS by the first delaying unit 401, such that the phase difference between the internal clock signal CLK and the received data strobe signal DQS becomes less than a first given amount. When a read instruction has been received, the detecting unit 404 continuously detects the phase difference during the read operation. Thus, during 1 read operation interval, if a change in phase difference information DQPHASE from the detecting unit 404 occurs, a pulse such as noise may be occurring in the data strobe signal DQS. Therefore, to prevent a change in the phase difference information DQPHASE from occurring during 1 read operation interval, the control unit 311 may fix the phase difference information DQPHASE during 1 read operation.

The delay of the data strobe signal DQS that has been subject to delay by the second delaying unit 402 is the second given amount described with reference to FIG. 2. The second delaying unit 402 includes a delaying unit 411, a delaying unit 412, and a delaying unit 413.

The acquiring unit 403 acquires at a timing based on the internal clock signal CLK, values of a data strobe that has been subject to delay by the control unit 311 and values of the data strobe signal DQS that has been subject to delay by the first delaying unit 401. The timing based on the internal clock signal CLK is, for example, the rising edge and/or the falling edge of the internal clock signal CLK. The acquiring unit 403 further acquires at a timing based on the internal clock signal CLK, values of the data strobe signal DQS that has been subject to delay by the delaying unit 411. The acquiring unit 403 acquires at a timing based on the internal clock signal CLK, values of the data strobe signal DQS that has been subject to delay by the delaying unit 412. The acquiring unit 403 further acquires at a timing based on the internal clock signal CLK, values of the data strobe signal DQS that has been subject to delay by the delaying unit 413.

For example, the acquiring unit 403 is implemented by latches 421 to 424. The latch 421 stores at the timing of the rising edge of the internal clock signal CLK, the value of the data strobe signal DQS that has been subject to delay by the control unit 311. The latch 422 stores at the timing of the rising edge of the internal clock signal CLK, values of the data strobe signal DQS that has been subject to delay by the delaying unit 411. The latch 423 stores at the timing of the rising edge of the internal clock signal CLK, values of the data strobe signal DQS that has been subject to delay by the delaying unit 412. The latch 424 stores at the timing of the rising edge of the internal clock signal CLK, values of the data strobe signal DQS that has been subject to delay by the delaying unit 413.

The phase/error detecting unit 312 outputs to the CPU 302 and as the error information Err1 and the error information Err2, respectively, the value stored by the latch 421 and the value stored by the latch 424. The error information Err1 and Err2 are data that can determine whether an abrupt change has occurred in either signal among the internal clock signal CLK and the data strobe signal DQS.

The detecting unit 404 regards the value stored by the latch 422 and the value stored by the latch 423 as phase information PHD1 and PHD2, and detects the phase difference between the data strobe signal DQS and the internal clock signal CLK. The detecting unit 404 outputs to the control unit 311, the phase difference information DQPHASE related to the detected phase difference. The phase difference detection method by the detecting unit 404, for example, may employ the conventional art example above. The control unit 311 adjusts the delay of the data strobe signal DQS, based on the phase difference information DQPHASE.

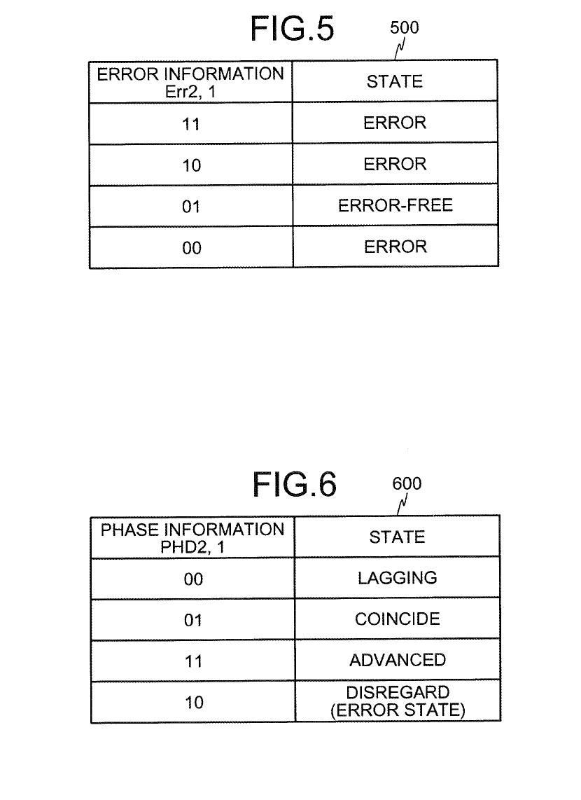

FIG. 5 is a table of error information. As depicted in a table 500, depending on the combination of the error information Err1 and the error information Err2, the potential of an abrupt change occurring in either signal among the internal clock signal CLK and the data strobe signal DQS is indicated.

For example, if the error information Err2 is “1” and the error information Err1 is “1”, an abrupt change in at least any one among the internal clock signal CLK and the data strobe signal DQS is possible. If the error information Err2 is “1” and the error information Err1 is “0”, an abrupt change in at least any one among the internal clock signal CLK and the data strobe signal DQS is possible. For example, if the error information Err2 is “0” and the error information Err1 is “1”, an error-free state is indicated in which no abrupt change has occurred in either the internal clock signal CLK or the data strobe signal DQS. For example, if the error information Err2 is “0” and the error information Err1 is “0”, an abrupt change in at least any one among the internal clock signal CLK and the data strobe signal DQS is possible.

FIG. 6 is a table of phase information. As depicted in a table 600, depending on the combination of the phase information PHD1 and the phase information PHD2, whether the phases of the internal clock signal CLK and the data strobe signal DQS coincide, or if one of the phases is lagging behind or is ahead of the other is indicated.

For example, if the phase information PHD2 is “0” and the phase information PHD1 is “0”, the phase of the received data strobe signal DQS is judged to be lagging behind the phase of the internal clock signal CLK. If the phase information PHD2 is “0” and the phase information PHD1 is “1”, the phase of the received data strobe signal DQS is judged to coincide with the phase the internal clock signal CLK. If the phase information PHD2 is “1” and the phase information PHD1 is “1”, the phase of the received data strobe signal DQS is judged to be ahead of the phase of the internal clock signal CLK. A state in which the phase information PHD2 is “1” and the phase information PHD1 is “0” does not occur and is therefore, disregarded.

For example, the occurrence of a state in which the phase information PHD2 and PHD1 are “00” or “11”, is not limited to an abrupt clock signal change. Even when the phase of the received data strobe signal DQS is judged to be ahead of the phase of the internal clock signal CLK, if the difference is not significant enough to affect the read operation, the potential of an error occurring in the read data signal DQ is low. Therefore, as described, in addition to the phase information PHD2 and PHD1, the error information Err2 and Err1 are generated by the memory controller 301.

FIGS. 7A, 7B, 7C, and 7D are timing charts of the data strobe signal and the internal clock signal. Timing charts 701 to 704 depicted in FIGS. 7A, 7B, 7C, and 7D depict the internal clock signal CLK and the data strobe signal DQS that as depicted in FIG. 4, is subject to delay by the delaying units before passing through the nodes. “” on the data strobe signal DQS represents the value acquired by the acquiring unit 403 at a timing based on the internal clock signal CK.

For example, in the timing chart 701, the error information Err2 and Err1 are “01” and an error-free state is depicted. The control unit 311 controls the delay of the data strobe signal DQS such that the phase detected by the detecting unit 404 is in a state like that depicted by the timing chart 701.

For example, the control unit 311 controls the delay of the data strobe signal DQS induced by the first delaying unit 401 such that the phase difference between the internal clock signal CLK and the data strobe signal DQS before passing the node_a becomes a given amount d11. For example, the delaying unit 411 delays the data strobe signal DQS output from the first delaying unit 401 such that the phase difference between the internal clock signal CLK and the data strobe signal DQS before passing the node_b becomes a given amount d12.

For example, the delaying unit 412 delays the data strobe signal DQS output from the delaying unit 411 such that the phase difference between the internal clock signal CLK and the data strobe signal DQS before passing the node_c becomes a given amount d13. For example, the delaying unit 413 delays the data strobe signal DQS output from the delaying unit 412 such that the phase difference between the internal clock signal CLK and the data strobe signal DQS before passing the node_d becomes a given amount d14. The phase difference between the data strobe signal DQS before passing the node_a and the data strobe signal DQS before passing the node_d is a second given amount d11.

In the timing chart 702, the error information Err2 and Err1 are “00”; a phase difference d21 is small compared to the given amount d11; and a phase difference d24 is large compared to the given amount d14. In the timing chart 702, relative to an error-free state, the data strobe signal DQS before passing the nodes a to d is slightly lagging and therefore, has an error.

In the timing chart 703, the error information Err2 and Err1 are “10”; a phase difference d31 is large compared to the given amount d11; and a phase difference d34 is large compared to the given amount d14. In the timing chart 703, relative to an error-free state, the data strobe signal DQS before passing the nodes a to d is significantly advanced or lagging, and therefore, has an error.

In the timing chart 704, the error information Err2 and Err1 are “11”; a phase difference d41 is large compared to the given amount d11; and a phase difference d44 is small compared to the given amount d14. In the timing chart 704, relative to an error-free state, the data strobe signal DQS before passing the nodes a to d is slightly advanced and therefore, has an error.

In the second example, the memory controller 301 judges whether an abrupt change has occurred. In the second example, components identical to those in the first example are given the same reference numerals used in the first example and description of identical functions is omitted.

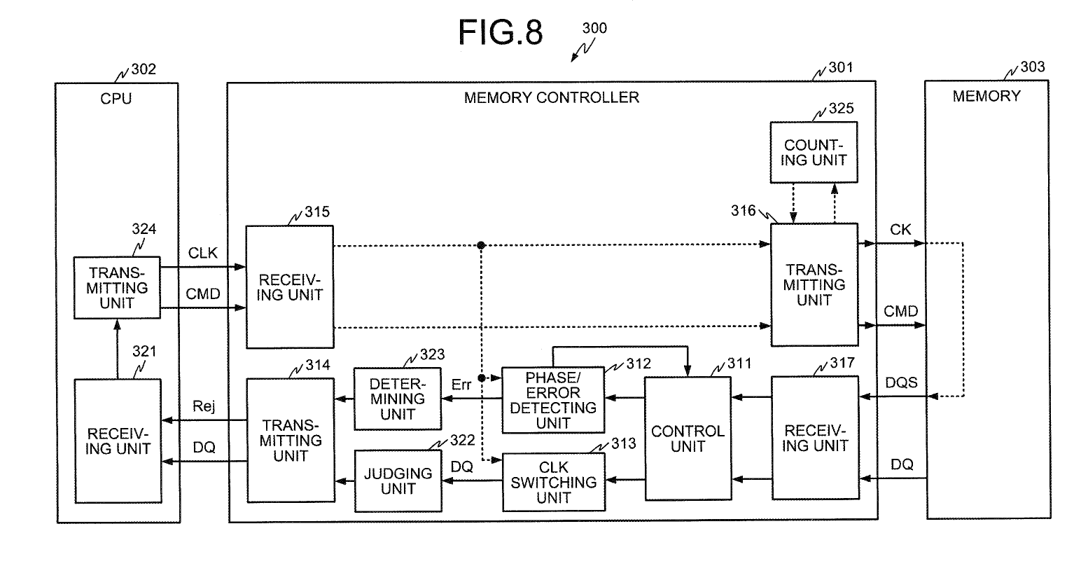

FIG. 8 is a diagram of an example of the memory controller according to the second example. The memory controller 301 includes the control unit 311, the phase/error detecting unit 312, the CLK switching unit 313, the transmitting unit 314, the receiving unit 315, the transmitting unit 316, the receiving unit 317, the judging unit 322, the determining unit 323, and the counting unit 325. For example, the CPU 302 includes the receiving unit 321 and the transmitting unit 324.

The judging unit 322 judges whether the data signal DQ after clock switching has an error. The determining unit 323 determines whether the error information Err is a predetermined value. In this example, the predetermined value is “01” as depicted in FIG. 5. If the determining unit 323 determines that the error information Err is not the predetermined value, the transmitting unit 316 transmits to the memory 303, the internal clock signal CLK and a command signal CMD that indicates a read instruction identical to the read instruction in the case of a determination that the error information Err is not the predetermined value. The transmitting unit 314 further transmits a request rejection Rej to the CPU 302, if the determining unit 323 determines that the error information Err is not the predetermined value.

The counting unit 325 counts the number of times that the same read instruction is transmitted to the memory 303 by the transmitting unit 316. The transmitting unit 314 does not transmit the same read instruction, if the count obtained by the counting unit 325 is greater than or equal to a given count. The given count is, for example, determined by the designer the system 300 and preliminarily stored to a storage device such as a register in the memory controller 301.

As a result, the read operation can be prevented from being performed indefinitely. Further, if the occurrence of an abrupt change has been determined, by performing the read operation again, the potential of performing error-free reading is high. Irrespective of the high potential of performing error-free reading and despite repeated execution of the read operation, if error-free reading still cannot be performed, a failure of the memory 303 and/or the memory controller 301 may have occurred. Accordingly, by using the counting unit 325 and limiting the number of executions of the read operation, the memory controller 301 can detect whether a failure of the memory 303 and/or the memory controller 301 has occurred. Further, if the count obtained by the counting unit 325 is greater than or equal to the given count, the CPU 302, for example, may output error information.

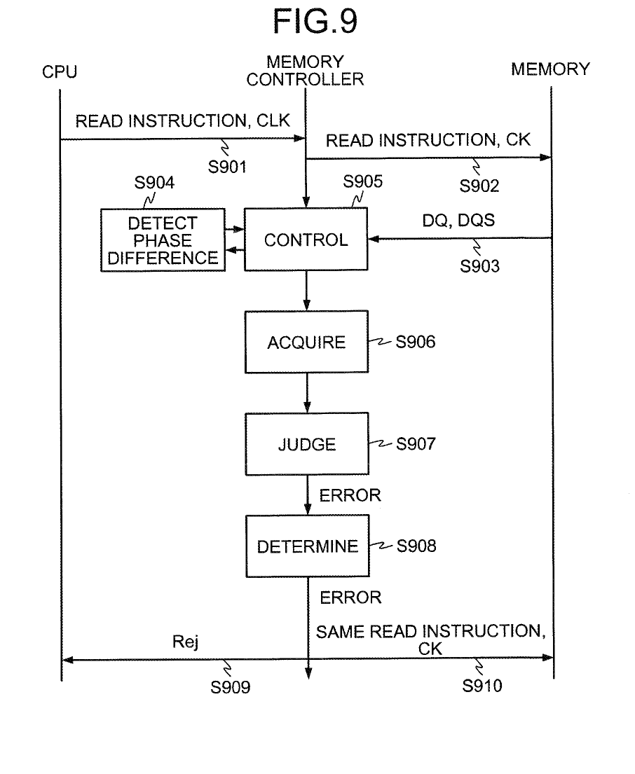

FIG. 9 is a diagram depicting the determination support process and the determination process. When a read operation is performed, the CPU 302 transmits to the memory controller 301, the clock signal CLK and a command signal CMD that indicates a read instruction (step S901). The memory controller 301 transmits to the memory 303, the internal clock signal CK that is based on the received clock signal CLK and a command signal CMD that indicates a read instruction that is based on the received command signal CMD (step S902). The memory 303 synchronizes the data signal DQ, which is based on an address indicating the read instruction, with the data strobe signal DQS that is based on the received internal clock signal CK, and transmits the data signal DQ to the memory controller 301 (step S903).

The memory controller 301 detects the phase difference between the internal clock signal CLK and the received data strobe signal DQS (step S904), and controls the delay of the received data strobe signal DQS such that the detected phase difference becomes less than the given amount (step S905). The memory controller 301 acquires at a timing based on the internal clock signal CLK, values of the data strobe signal DQS that has been subject to delay (step S906). Here, the values acquired at step S906 are the error information Err. Operations at steps S904 to S906 are continually performed.

The memory controller 301 judges whether the data signal DQ received from the memory 303 has an error (step S907). If the data signal DQ received from the memory 303 has an error (step S907: error), the memory controller 301 determines whether the error information Err is the predetermined value (step S908). If the error information Err is not the predetermined value (step S908: error), the memory controller 301 rejects the request from the CPU 302 (step S909), and transmits the same read instruction and the internal clock signal CK to the memory 303 (step S910).

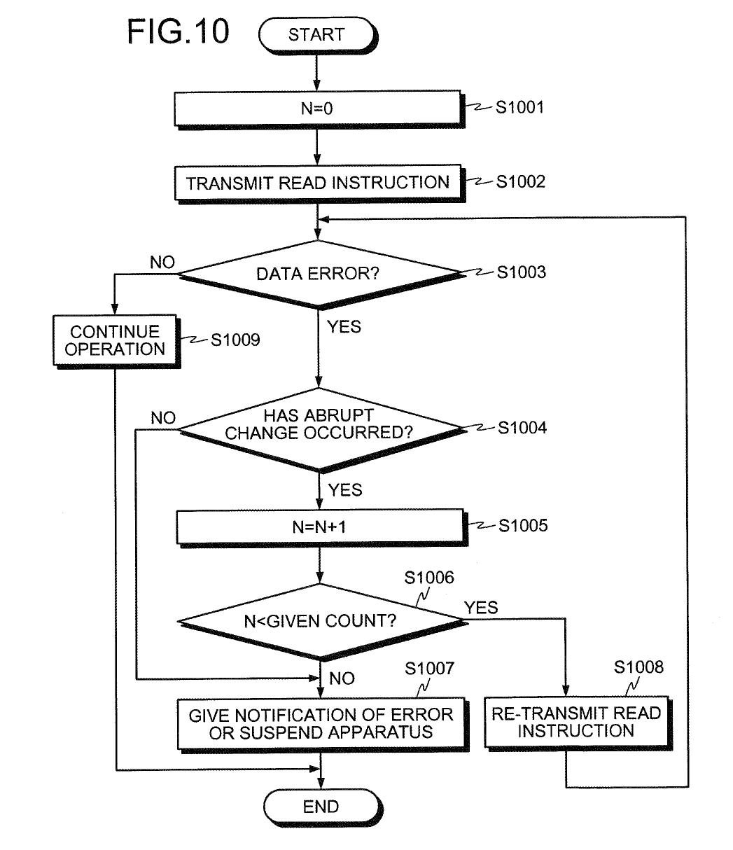

FIG. 10 is a flowchart of the determination process. Although the determination process depicted in FIG. 10 may be performed by either the memory controller 301 or the CPU 302, herein, the determination process will be described as a process by the memory controller 301.

The memory controller 301, upon receiving a read instruction from the CPU 302, sets N=0 (step S1001), and transmits the read instruction to the memory 303 (step S1002). The memory controller 301, upon receiving the data signal DQ from the memory 303, judges whether the data has an error (step S1003).

If the data has an error (step S1003: YES), the memory controller 301 determines whether the error information Err is the predetermined value and thereby, determines whether an abrupt change has occurred in the internal clock signal CLK and/or the data strobe signal DQS (step S1004).

If no abrupt clock signal change has occurred (step S1004: NO), the memory controller 301 transitions to step S1007. If an abrupt clock signal change has occurred (step S1004: YES), the memory controller 301 sets N=N+1 (step S1005), and determines whether N<the given count is true (step S1006). If N<the given count is true (step S1006: YES), the memory controller 301 re-transmits the read instruction (step S1008), and returns to step S1003. At step S1008, the memory controller 301 may further transmit a request rejection Rej to the CPU 302.

If N<the given count is not true (step S1006: NO), the memory controller 301 gives notification of an error or suspends the apparatus (step S1007), ending the determination process. Here, the apparatus may be the system 300, or the memory 303 and the memory controller 301.

At step S1003, if the data signal DQ is judged to have no error (step S1003: NO), the memory controller 301 continues operation (step S1009), ending the determination process.

FIG. 11 is a diagram of an example of a motherboard to which the memory controller according to the embodiment has been applied. A motherboard 1100 is equipped with the CPU 302 and a socket 1101. The CPU 302 is equipped with the memory controller 301. In the socket 1101, a memory board 1102 is mounted. Further, the socket 1101 may be disposed in plural on the motherboard 1100.

As described, the determination support apparatus acquires by the first clock signal, values of the second clock signal that has been subject to phase feedback control such that the detection result of the phase difference between the first and the second clock signals approaches the given amount. As a result, data can be obtained that can determine whether an abrupt change has occurred in either clock signal among the first clock signal and the second clock signal. Consequently, by referring to the data, whether an abrupt clock signal change has occurred can be determined. For example, if an error has occurred in data generated based on the clock signals, whether the error occurred consequent to an abrupt clock signal change or a factor other than an abrupt clock signal change can be determined.

The determination support apparatus further delays by the given amount, the second clock signal that has been delayed, and at a timing of the first clock signal, acquires values of the resulting delayed second clock signal and of the second clock signal after the initial delay. As a result, data is obtained that can determine whether an abrupt clock signal change has occurred that causes the phase of the first clock signal to lag behind the phase of the second signal. Further, data is obtained that can determine whether an abrupt clock signal change has occurred that causes the phase of the first clock signal to be ahead of the phase of the second clock signal. Consequently, determination accuracy can be improved.

The determining apparatus determines whether the acquired values are the predetermined value and thereby, determines whether an abrupt clock signal change has occurred.

As described, the memory controller acquires at a timing that is based on the internal clock signal, values of a data strobe signal subject to phase feedback control such that the detection result of the phase difference between the internal clock signal and the data strobe signal approaches the given amount. As a result, data can be obtained that can determine whether an abrupt clock signal change has occurred in either signal among the internal clock signal and the data strobe signal. Consequently, by referring to this data, the CPU can determine whether an abrupt clock signal change has occurred.

For example, if a read data signal has an error, whether the error is consequent to an abrupt clock signal change or a factor other than an abrupt clock signal change cannot be determined conventionally. If an abrupt clock signal change is the cause, re-execution of the read operation may enable error-free data to be read. However, since the cause of an error cannot be determined conventionally, the user of the system in which the memory and/or memory controller is equipped judges that an apparatus such as the memory or the memory controller has failed and replaces the apparatus. On the other hand, with the memory controller of the embodiment, whether a data error occurred consequent to an abrupt clock signal change or a factor other than an abrupt clock signal change can be determined. As a result, whether an apparatus has failed can be more accurately determined.

Further, the memory controller determines whether the acquired values are the predetermined value and if the values are not the predetermined value, the memory controller transmits the same read instruction and the internal clock signal to the memory. If an abrupt clock signal change has occurred, read data may have an error and therefore, by re-reading the data, the potential of obtaining error-free data increases.

If data received from the memory is judged to have an error, the memory controller determines whether the acquired values are the predetermined value. For example, in a system in which the occurrence of signal noise has a high potential, the occurrence of an abrupt clock signal change is high. An abrupt clock signal change that does not affect the read data may also occur. Therefore, if the read data has no error, by disregarding whether an abrupt clock signal change has occurred, frequent occurrences of read operations can be prevented.

Further, for example, if the occurrence of an abrupt change is determined despite repeatedly transmitting the read instruction, the memory controller and/or the memory may have a problem and therefore, the read operation can be prevented from being recursively performed indefinitely. The memory controller counts the number of times that the same read instruction is transmitted and if the count exceeds the given count, the memory controller ceases retransmission of the signal.

According to the embodiment, data can be obtained that can determine whether an abrupt clock signal change has occurred.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A determination support apparatus comprising
a detecting unit that detects a phase difference between a first clock signal and a second clock signal that is identical in frequency to the first clock signal;
a control unit that controls delay of at least any one among the first clock signal and the second clock signal such that the detected phase difference becomes less than a given amount; and
an acquiring unit that acquires values of a given clock signal among the first clock signal and the second clock signal, among which at least one has been subject to delay control by the control unit, wherein the acquiring unit acquires the values of the given clock signal at a timing that is based on a clock signal that is other than the given clock signal and among the first clock signal and the second clock signal, among which at least one has been subject to delay control.

2. The determination support apparatus according to claim 1, further comprising
a delaying unit that delays the given clock signal by a second given amount, wherein
the acquiring unit acquires at a timing that is based on the clock signal other the given clock signal, the values of the given clock signal before and after the given clock is delayed by the second given amount.

3. The determination support apparatus according to claim 1, further comprising
a delaying unit that delays the clock signal other than the given clock signal by a second given amount, wherein
the acquiring unit acquires the values of the given clock signal, at timings that are based on the clock signal other the given clock signal, before and after the clock signal other than the given clock is delayed by the second given amount.

4. A determining apparatus comprising:
a detecting unit that detects a phase difference between a first clock signal and a second clock signal of a frequency identical to the frequency of the first clock signal;
a control unit that controls at least any one among the first clock signal and the second clock signal such that the detected phase difference becomes less than a given amount;
an acquiring unit that acquires values of a given clock signal among the first clock signal and the second clock signal, among which at least one has been subject to delay control by the control unit, wherein the acquiring unit acquires the values of the given clock signal at a timing that is based on a clock signal other than the given clock signal and among the first clock signal and the second clock signal, among which at least one has been subject to delay control; and
a determining unit that determines whether the acquired values are a predetermined value.

5. A system comprising:
a processor that executes data processing;
memory storing data; and
a memory controller that upon receiving a read instruction from the processor, transmits the read instruction and an internal clock signal to the memory, and that receives from the memory, a data strobe signal that is generated based on the internal clock signal by the memory and has a cycle identical to that of the internal clock signal, and data that is synchronized with the data strobe signal and transmitted, the memory controller comprising:
a detecting unit that detects a phase difference between the internal clock signal and the received data strobe signal;
a control unit that controls delay of the received data strobe signal such that the detected phase difference is less than a given amount; and
an acquiring unit that acquires at a timing that is based on the internal clock signal, values of the data strobe signal that has been subject to delay control by the control unit.

6. The memory controller according to claim 5, further comprising:
a determining unit that determines whether the acquired values are a predetermined value; and
a transmitting unit that when the determining unit determines that the acquired values are not the predetermined value, transmits to the memory, a read instruction identical to the read instruction when the determining unit determines that the acquired values are not predetermined value and the internal clock signal.

7. The memory controller according to claim 6, wherein
the determining unit, when data received from the memory is judged to have an error, determines whether the acquired values are the predetermined value.

8. The memory controller according to claim 6, further comprising
a counting unit that counts transmissions of the read instruction identical to the read instruction when the determining unit determines that the acquired values are not predetermined value, transmitted to the memory by the transmitting unit, wherein
the transmitting unit, when a count obtained by the counting unit is greater than or equal to a given count, does not transmit the read instruction identical to the read instruction when the determining unit determines that the acquired values are not predetermined value.
